(19) United States
(12) Patent Application Publication
(10) Pub. No.: US 2007/0176182 A1
(43) Pub. Date: Aug. 2, 2007

(54) Structure for integrating LED circuit onto heat-dissipation substrate

(76) Inventors: Way-Jze Wen, Lung Tan (TW); Yi-Fong Lin, Lung Tan (TW); Shyi-Ming Pan, Lung Tan (TW); Chih-Wei Chiang, Lung Tan (TW); Yin-Cheng Chu, Lung Tan (TW); Huan-Che Tseng, Lung Tan (TW); Fen-Ren Chien, Taoyuan County (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/340,660

(22) Filed: Jan. 27, 2006

(51) Int. Cl. H01L 33/00

(52) U.S. Cl. 257/79

(57) ABSTRACT

A structure for integrating LED circuit onto a heat-dissipation substrate is disclosed. At least an electronic component and a LED chip are integrated on a heat-dissipation substrate. The electronic component can be a passive component, a drive chip, an electrostatic discharge protection device, or a sensing component. Therefore, both wire-bonding area of the LED chip and the series resistance of wires are reduced while the heat dissipation efficiency is enhanced.

### BACKGROUND OF THE INVENTION

The present invention relates to a light emitting diode, especially to a structure that integrates LED circuit on a heat-dissipation substrate.

Light emitting diode (LED) with features of compact structure, long lifetime, low power consumption, fast reaction, and good directing effect has been applied to electrical appliances, computers and communication products.

Generally, in order to achieve the purpose of high brightness, it is necessary to increase light-emitting efficiency of the LED and allow maximum current input. There are two factors that have influence on the maximum current input-resistance of the LED and heat dissipation capacity of the substrate loaded with the LED chip. Poor heat dissipation capacity limits the maximum amount of current input. Due to the facts that the glass translation temperature of the package material and lens material of LED is not high, and the efficiency of LED decreases with increasing temperature, the operation temperature of LED needs to be controlled within a certain range.

Refer to Taiwanese patent No. 243788, applied on Aug. 14, 2003, a heat dissipation structure for light-emitting component is disclosed. The device includes a heat dissipation substrate made from metal and a printed circuit board that attach with each other by thermal grease. At least one opening is disposed on the printed circuit board and the opening connects with the heat dissipation substrate. Circuits are etched on surface copper layer of the printed circuit board. At least one LED chip is mounted on the opening and the bottom of the chip is attached on surface of the heat dissipation substrate by the thermal grease so that the heat generated by the LED chip is transmitted to the heat dissipation substrate. Pins of each LED chip connect with the circuit on the printed circuit board. Insulated epoxide is filled into the opening for coating the LED chip so as to avoid short circuit. Thus the heat generated from the LED chip is conducted and dissipated through the heat dissipation substrate so that the operation temperature of LED chip while emitting light is controlled within a safe range. If the device needs to connect with a drive chip, a further external circuit board is necessary.

If the LED chip is attached directly on the printed circuit board, the problem of thermal conductivity is raised. If the LED chip is disposed on a heat dissipation substrate, it is necessary to further connect with a printed circuit board so that the wire-bonding area of the LED chip is enlarged and the series resistance of wires is increased. Moreover, the LED chip is also joined with at least one electronic component for driving or electrostatic discharge protection. For electrically connection of the electronic component, it is necessary to connect with an external printed circuit board. Therefore, there is a need to solve the problems mentioned above.

### SUMMARY OF THE INVENTION

Therefore it is a primary object of the present invention to provide a LED circuit integrated with a heat-dissipation substrate that disposes at least electronic component such as a passive component, a drive chip, an electrostatic discharge protection device, or a sensing component on the heat-dissipation substrate so that the electronic component necessary for LED is integrated on the heat-dissipation substrate.

It is another object of the present invention to provide a LED circuit integrated with a heat-dissipation substrate that is made from high thermal conductive material, conductive material, or combinations of above materials.

It is a further object of the present invention to provide a LED circuit integrated with a heat-dissipation substrate that the heat-dissipation substrate is electrically connected with the LED chip so as to reduce wire bonding area of the LED chip as well as reduce the series resistance of wires.

In order to achieve above objects, the present invention provides a LED circuit integrated with a heat-dissipation substrate. At least one electronic component such as a passive component, a drive chip, an electrostatic discharge protection device, or a sensing component is integrated on a heat-dissipation substrate so as to reduce wire-bonding area of the LED chip and decrease the series resistance of wires.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing of a top view LED in accordance with the present invention;

FIG. 2 is a schematic drawing of another embodiment of the top view LED in accordance with the present invention;

FIG. 3 is a schematic drawing of a flip chip LED in accordance with the present invention;

FIG. 4 is a schematic drawing of another embodiment of the flip chip LED in accordance with the present invention;

FIG. 5 is a cross sectional view of a LED chip and an electronic component on an embodiment in accordance with the present invention; and

FIG. 6 is a perspective view showing a LED chip and an electronic component of an embodiment in accordance with the present invention.

### DETAILED DESCRIPTION OF THE PREFFERED EMBODIMENT

The conventional way of die bonding uses a high heat-dissipation substrate to dissipate heat and a printed circuit board is used to electrically connect with the LED chip. Or the die is bonded to the printed circuit board so that the problems of wire-bonding and heat dissipation are raised. Therefore, the present invention provides a LED structure that solves the problems by integrating at least one electronic component on the heat-dissipation substrate.

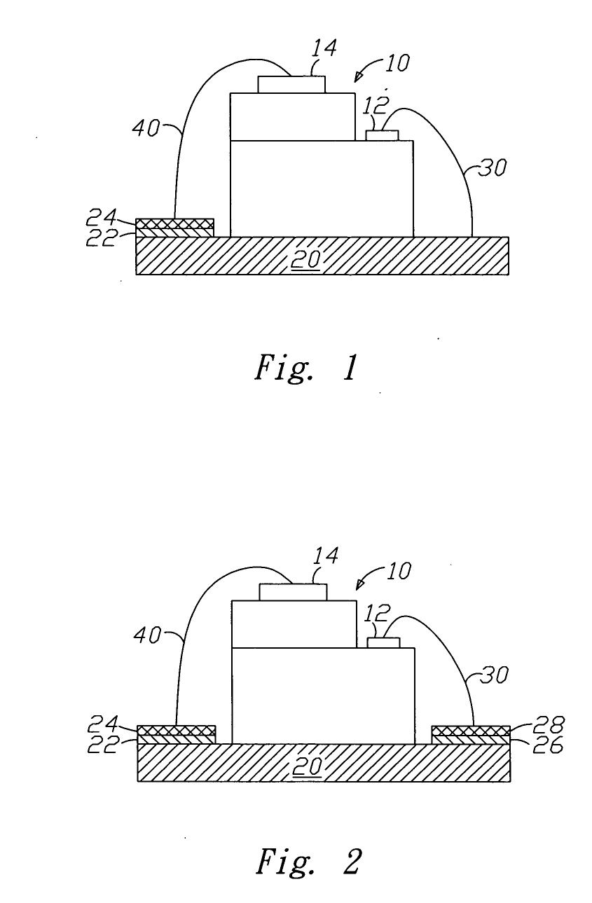

Refer to FIG. 1, the present invention discloses a LED circuit integrated with a heat-dissipation substrate that includes a LED chip 10 and a heat-dissipation substrate 20.

A first electrode 12 of the LED chip 10 electrically connects with the heat-dissipation substrate 20 through a first wire 30. A first insulating layer 22, and a first circuit layer 24 are disposed on the heat-dissipation substrate 20 in sequence. And a second electrode 14 of the LED chip 10 electrically connects with the first circuit layer 24 through a second wire 40.

Moreover, refer to FIG. 2, a top emitting LED of an embodiment according to the present invention consists of a second insulating layer 26, and a second circuit layer 28 arranged on the heat-dissipation substrate 20 sequentially. A first electrode 12 of the LED chip 10 electrically connects with the second circuit layer 28 through a first wire 30.

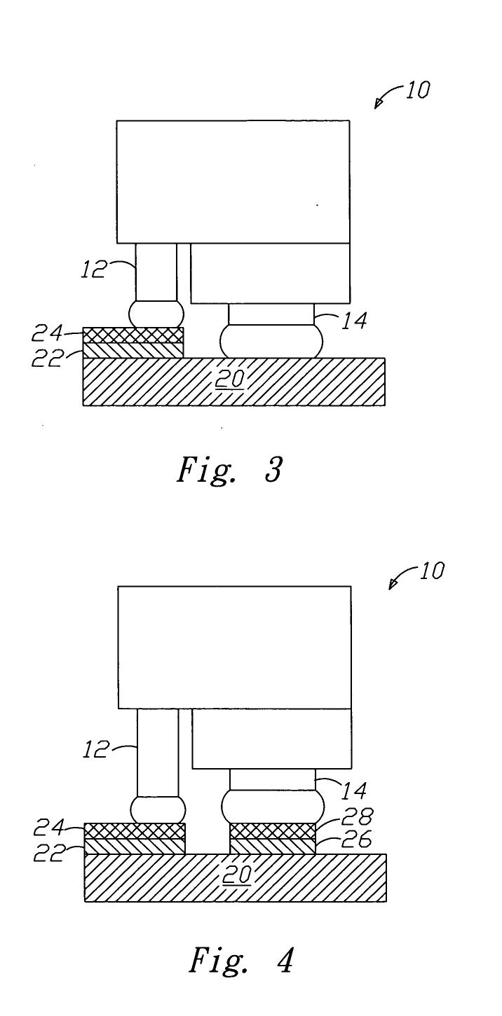

Furthermore, the present invention is applied to package of the flip-chip type LED. Refer to FIG. 3, a LED circuit integrated with a heat-dissipation substrate according to the present invention is composed of a LED chip 10 and a heat-dissipation substrate 20.

A first electrode 12 of the LED chip 10 electrically connects with the heat-dissipation substrate 20 through a first wire 30. A first insulating layer 22, and a first circuit layer 24 are disposed on the heat-dissipation substrate 20 in sequence. And a second electrode 14 of the LED chip 10 electrically connects with the first circuit layer 24 through a second wire 40.

In addition, as shown in FIG. 4, a flip-chip LED of an embodiment in accordance with the present invention includes a second insulating layer 26 and a second circuit layer 28 arranged on the heat-dissipation substrate 20 sequentially. A first electrode 12 of the LED chip 10 electrically connects with the second circuit layer 28 through a first wire 30.

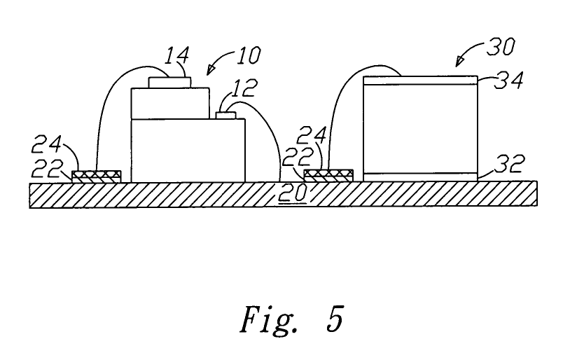

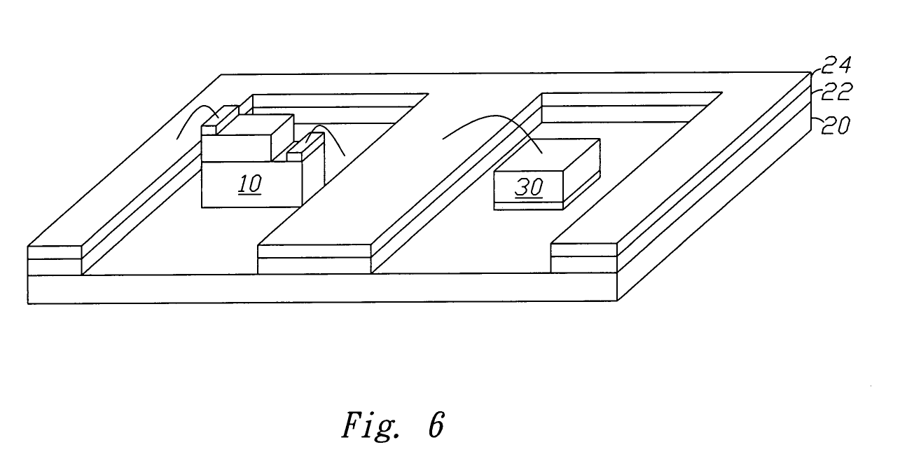

Refer to FIG. 5 & FIG. 6, a LED circuit integrated with a heat-dissipation substrate in accordance with the present invention includes a LED chip 10, at least one electronic component 30 and a heat-dissipation substrate 20.

The electrically connection way of the LED chip 10 can be above two ways and the electronic component is electrically connected with the heat-dissipation substrate 20 in similar way to the LED chip 10. This embodiment take top view LED chip and the electronic component electrically connected with the heat-dissipation substrate as an example. A first electrode 12 of the LED chip 10 and a third electrode 32 of the electronic component 30 are electrically connected with the heat-dissipation substrate 20 while an insulating layer 22 and a circuit layer 24 are sequentially arranged on the heat-dissipation substrate 20. And a second electrode 14 of the LED chip 10 as well as a fourth electrode 34 of the electronic component 30 is electrically connected with the circuit layer 24.

The reason that the present invention provides the heat-dissipation substrate 20 to the LED chip 10 for dissipating heat instead of directly attaching dies to a printed circuit board is due to poor heat dissipation of the printed circuit board. Moreover, by the way that the circuit is directly designed onto the heat-dissipation substrate 20 during the manufacturing process, the electronic component 30 is electrically connected with the heat-dissipation substrate 20 so that both the wire bonding area and the series resistance of wires are reduced. There is no need for the device to connect with an external printed circuit board that the prior art does.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A structure for integrating light emitting diode circuit onto a heat dissipation substrate comprising:
a light emitting diode chip; and
a heat dissipation substrate that connects with the light emitting diode chip and includes at least one electronic component;
wherein an insulating layer and a circuit layer are sequentially disposed on the heat dissipation substrate while the circuit layer is electrically connected with the light emitting diode chip as well as the electronic component.

2. The structure as claimed in claim 1, wherein the light emitting diode chip is in flip chip package or surface mounting device (SMD) package.

3. The structure as claimed in claim 1, wherein the heat dissipation substrate is made from conductive material or semiconductor material.

4. The structure as claimed in claim 1, wherein the heat dissipation substrate is made from metal.

5. The structure as claimed in claim 1, wherein the electronic component is a passive component.

6. The structure as claimed in claim 1, wherein the electronic component is a drive chip.

7. The structure as claimed in claim 1, wherein the electronic component is an electrostatic discharge protection device.

8. The structure as claimed in claim 1, wherein the electronic component is a sensing component.

9. The structure as claimed in claim 1, wherein the LED chip is a LED chip with a horizontal electrode or a vertical electrode.

10. The structure as claimed in claim 1, wherein a first electrode and a second electrode of the light emitting diode chip are electrically connected with the heat dissipation substrate and the circuit layer respectively.

11. The structure as claimed in claim 1, wherein a first electrode and a second electrode of the light emitting diode chip are electrically connected with the circuit layer.

12. The structure as claimed in claim 1, wherein a first electrode and a second electrode of the electronic component are electrically connected with the heat dissipation substrate and the circuit layer respectively.

13. The structure as claimed in claim 1, wherein a first electrode and a second electrode of the electronic component are electrically connected with the circuit layer.

14. A structure for integrating light emitting diode circuit onto a heat dissipation substrate comprising:
a light emitting diode chip; and
a heat dissipation substrate connected with the light emitting diode chip and disposed with at least one electronic component.

15. The structure as claimed in claim 14, wherein the light emitting diode chip is in flip chip package or surface mounting device (SMD) package.

16. The structure as claimed in claim 14, wherein the heat dissipation substrate is made from conductive material or semiconductor material.

17. The structure as claimed in claim 14, wherein the heat dissipation substrate is made from metal.

18. The structure as claimed in claim 14, wherein the electronic component is a passive component.

19. The structure as claimed in claim 14, wherein the electronic component is a drive chip.

20. The structure as claimed in claim 14, wherein the electronic component is an electrostatic discharge protection device.

21. The structure as claimed in claim 14, wherein the electronic component is a sensing component.

22. The structure as claimed in claim 14, wherein the LED chip is a LED chip with a horizontal electrode or a vertical electrode.
